(19) United States
(12) Patent Application Publication
(10) Pub. No.: US 2014/0045344 A1
(43) Pub. Date: Feb. 13, 2014

(54) COATER APPARATUS AND COATING METHOD

(71) Applicant: KABUSHIKI KAISHA TOSHIBA, Tokyo (JP)

(72) Inventor: Masashi TERAO, Yokkaichi (JP)

(73) Assignee: KABUSHIKI KAISHA TOSHIBA, Tokyo (JP)

(21) Appl. No.: 13/763,001

(22) Filed: Feb. 8, 2013

(30) Foreign Application Priority Data
Aug. 10, 2012 (JP) 2012-178206

(51) Int. Cl. H01L 21/02

(52) U.S. Cl. CPC H01L 21/02282
USPC 438/782; 118/313; 118/620

(57) ABSTRACT

A coater apparatus that coats a substrate with a chemical liquid includes a chemical liquid nozzle, a solvent nozzle, a solvent bath, a dummy dispense port, and an ionizer. The chemical liquid nozzle dispenses the chemical liquid onto the substrate. The solvent nozzle dispenses a solvent onto the substrate. The solvent bath contains a solvent and stores a tip of the chemical liquid nozzle when the chemical liquid nozzle is in standby such that the tip is exposed to a solvent vapor. The dummy dispense port exhausts the chemical liquid being dummy dispensed from the chemical liquid nozzle and stores the solvent nozzle when the solvent nozzle is in standby. The ionizer ionizes an atmosphere around the dummy dispense port.

### CROSS-REFERENCE TO RELATED APPLICATION(S)

This application is based upon and claims the benefit of priority from Japanese Patent Application No. 2012-178206, filed on, Aug. 10, 2012 the entire contents of which are incorporated herein by reference.

### FIELD

Embodiments disclosed herein generally relate to a coater apparatus and a method of coating.

### BACKGROUND

Some coater apparatuses are provided with a so called “dummy dispensing” feature in which liquid dispensing nozzle(s), when idle, is configured to discharge liquid(s) into an exhaust port to prevent drying or solidification of residual liquid at the tip of the liquid dispensing nozzles.

For instance, in a semiconductor manufacturing application, a spin coater typically used for coating resist onto a wafer may be provided with a chemical liquid dispense nozzle, a prewet nozzle, a solvent bath, and an exhaust port which may also be referred hereinafter as a dummy dispense port. When in standby, the chemical liquid dispense nozzle is retracted within the solvent bath, whereas the prewet nozzle, typically dispensing a thinner liquid prior to the coating, is retracted within the dummy dispense port.

In order to prevent the chemical liquid, which is a resist in this example, from solidifying at the tip of the chemical liquid nozzle and possibly contaminating the wafer, the chemical liquid nozzle is relocated to the dummy dispense port on a regular basis or prior to the resist coating to exhaust or dummy dispense the resist into the dummy dispense port from the tip of the chemical liquid dispense nozzle.

The prewet nozzle, on the other hand, may pick up contaminants on its tip, thereby possibly contaminating the wafer when the wafer is prewetted with the contaminated prewet nozzle. In semiconductor device manufacturing, a contaminated wafer results in poor yield and rework which in turn causes productivity degradation.

### BRIEF DESCRIPTION OF THE DRAWINGS

FIG. 1 is a vertical cross sectional side view of a coater apparatus and indicates a first embodiment.

FIG. 2 is a top view illustrating the upper surface of the coater apparatus.

FIG. 3 describes how dummy dispensing is carried out.

FIG. 4 corresponds to FIG. 1 and illustrates a second embodiment.

FIG. 5 corresponds to FIG. 1 and illustrates a third embodiment.

FIG. 6 corresponds to FIG. 1 and illustrates a fourth embodiment.

FIG. 7 corresponds to FIG. 1 and illustrates a fifth embodiment.

FIG. 8 corresponds to FIG. 1 and illustrates a sixth embodiment.

FIG. 9 is a block diagram indicating the configuration of a control device.

### DESCRIPTION

In one embodiment, a coater apparatus that coats a substrate with a chemical liquid is disclosed. The coater apparatus includes a chemical liquid nozzle, a solvent nozzle, a solvent bath, a dummy dispense port, and an ionizer. The chemical liquid nozzle dispenses the chemical liquid onto the substrate. The solvent nozzle dispenses a solvent onto the substrate. The solvent bath contains a solvent and stores a tip of the chemical liquid nozzle when the chemical liquid nozzle is in standby such that the tip is exposed to a solvent vapor. The dummy dispense port exhausts the chemical liquid being dummy dispensed from the chemical liquid nozzle and stores the solvent nozzle when the solvent nozzle is in standby. The ionizer ionizes an atmosphere around the dummy dispense port.

Embodiments are described hereinafter with reference to the accompanying drawings. Elements that are identical or similar across the embodiments are represented by identical or similar reference symbols. The drawings are not drawn to scale and thus, do not reflect the actual appearance or measurements of the features.

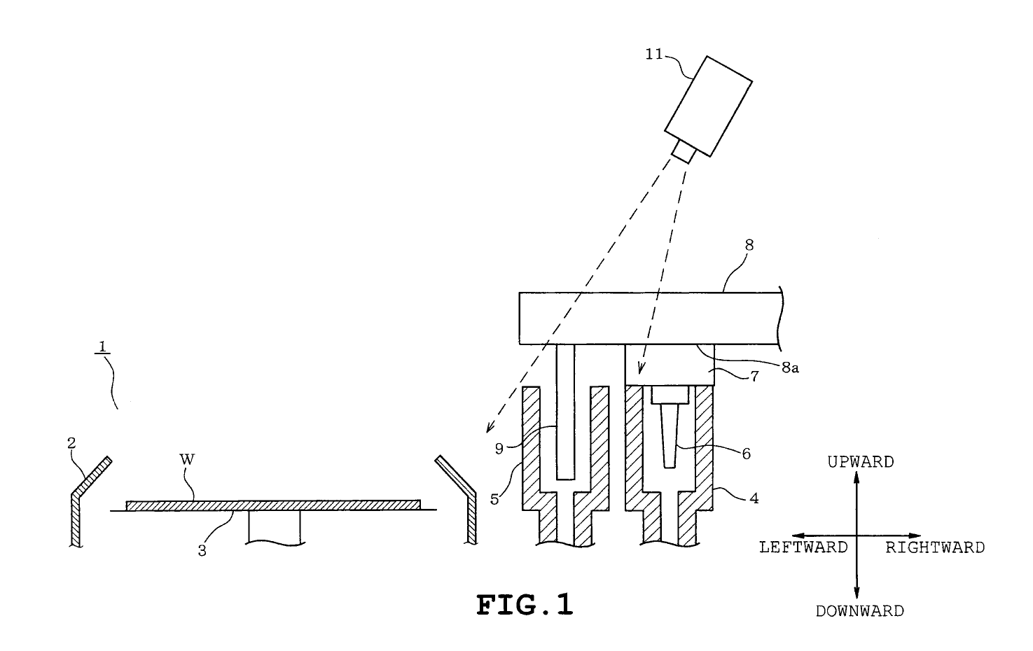

FIGS. 1 to 3 illustrate a first embodiment. FIG. 1 is a vertical cross sectional view illustrating the general configuration of coater apparatus 1 of the first embodiment. As shown in FIG. 1, coater apparatus 1 is provided with coater cup 2 and spin chuck 3. Spin chuck 3 is disposed rotatably within coater cup 2 and is configured to support a semiconductor substrate which is hereinafter also referred to as wafer W. Wafer W, being placed on spin chuck 3, is secured to spin chuck 3 by vacuum contact. Coater cup 2 further contains an edge cut nozzle and a back side rinse nozzle neither of which is shown that supply rinse liquid into a predetermined region of wafer W.

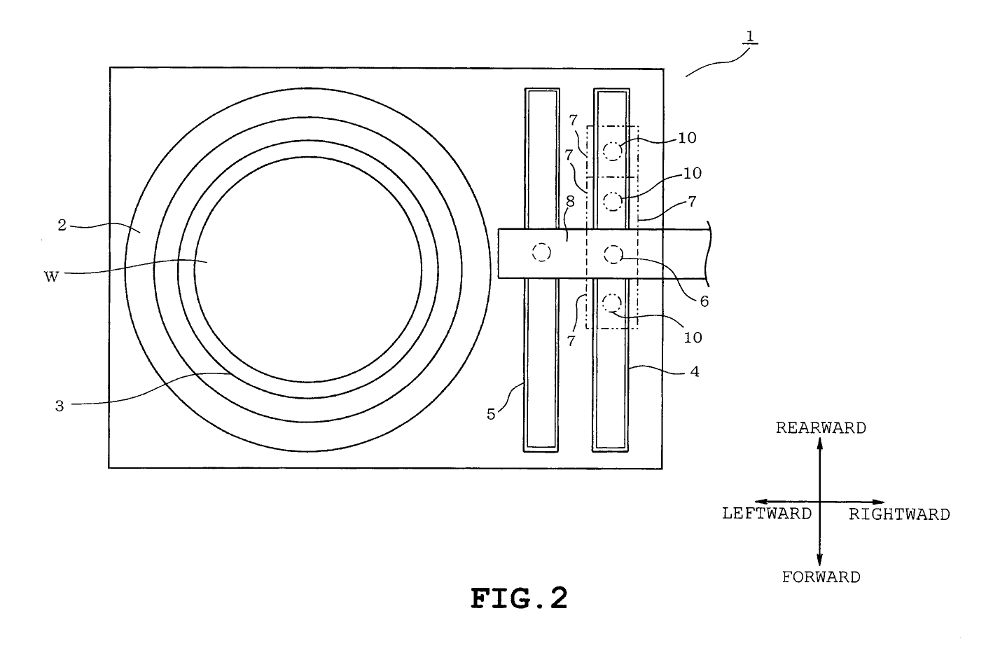

Outside coater cup 2, solvent bath 4 and dummy dispense port 5 are disposed next to one another. Solvent bath 4 contains a solvent and dummy dispense port 5 receives waste coating liquid discharged from a later described chemical liquid nozzle. FIG. 2 is a top view illustrating the general configuration of the upper surface of the coater apparatus. As shown in FIG. 2, solvent bath 4 and dummy dispense port 5 are each configured in the shape of a top-opening tub elongate in the forward and rearward directions as viewed in FIG. 2.

The first embodiment exemplifies a case in which the chemical liquid being supplied onto wafer W is a resist. Thus, chemical liquid nozzle 6 may hereinafter also be referred to as resist nozzle 6. Resist nozzle 6 is stored inside solvent bath 4 when idle, or in other words, when in a standby position. On the base end of resist nozzle 6, which corresponds to the upper end of resist nozzle 6 as viewed in FIG. 1, a rectangular mount 7 is provided. When resist nozzle 6 is in standby, the underside of the left and right ends of mount 7 rests on the upper end of solvent bath 4 as viewed in FIGS. 1 and 2, thereby placing resist nozzle 6 inside solvent bath 4 as described earlier. Mount 7 of resist nozzle 6 is detachably attached to nozzle mount 8a. Nozzle mount 8a is provided on the underside of hand 8 as shown in FIG. 1. Hand 8 is located at the tip of a robotic arm, the entirety of which is not shown. Hand 8 may be moved for example in the X, Y, and Z directions through the movement of the robotic arm. On the left end underside of hand 8 as viewed in FIG. 1, the base end of prewet nozzle 9 is attached which is may also be more generally referred to as solvent nozzle 9. As shown in FIG. 1, when in standby, resist nozzle 6 is stored inside solvent bath 4 whereas prewet nozzle 9 is stored in dummy dispense port 5. Solvent bath 4 contains solvent as described earlier, and thus, when resist nozzle 6 is stored inside solvent bath 4 during standby, the tip of resist nozzle 6 is exposed to solvent vapor. When the tip of prewet nozzle 9 is stored inside dummy dispense port 5 during standby, prewet nozzle 9 may also be dummy dispensed as required to exhaust solvent into dummy dispense port 5.

Apart from resist nozzle 6, coater apparatus 1 is provided with multiple chemical liquid nozzles 10 as shown in FIG. 2 that dispense different types of chemical liquids. These chemical liquid nozzles 10 are also stored in solvent bath 4 during standby as indicated by double-dot chain line in FIG. 2. On the base end of each chemical liquid nozzle 10, rectangular mount 7 is provided. When each of the chemical liquid nozzles 10 is in standby, the underside of the left and right ends of mount 7 rests on the upper end of solvent bath 4, thereby placing each chemical liquid nozzle 10 inside solvent bath 4 as described earlier. Mount 7 of each chemical liquid nozzle 10 is detachably attached to nozzle mount 8a. Nozzle mount 8a is provided on the underside of hand 8 located at the tip of a robotic arm. Hand 8 is configured to selectively attach a given nozzle from the choice of resist nozzle 6 and multiple chemical liquid nozzles 10.

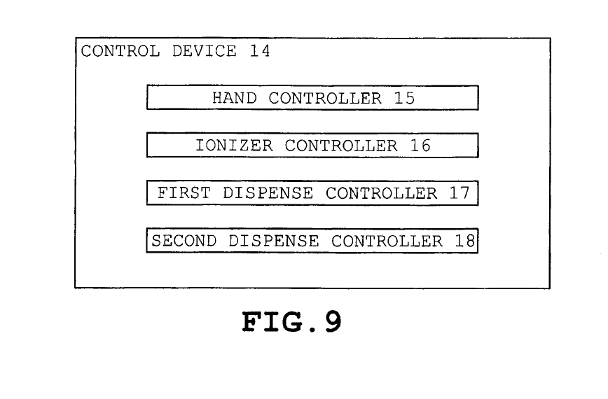

Referring back to FIG. 1, coater apparatus 1 is further provided with ionizer 11. The first embodiment employs soft X-ray radiation ionizer 11. Soft X-ray radiation ionizer 11 radiates soft X-ray as indicated by broken line in FIG. 1 to ionize the air or atmosphere near or in the periphery of dummy dispense port 5. Thus, if dummy dispense port 5 and its nearby components or air carry static electricity, the static electricity can be neutralized by the air ionization. Coater apparatus 1 is still further provided with a control device 14 schematically indicated in the block diagram of FIG. 9. Control device 14 may be configured by sub-control portions such as hand controller 15, ionizer controller 16, first dispense controller 17, and second dispense controller 18. Hand controller 15 controls the movement of the robotic arm and consequently hand 8 that carries resist nozzle 6 and solvent nozzle 9. Ionizer controller 16 activates or inactivates ionizer 11. First dispense controller 17 controls the dispensing and dummy dispensing of resist nozzle 6 and second dispense controller 18 controls the dispensing and dummy dispensing of solvent nozzle 9. Though only first and second dispense controllers 17 and 18 are shown, additional dispense controllers may be provided for controlling the dispensing and dummy dispensing of other types of nozzles.

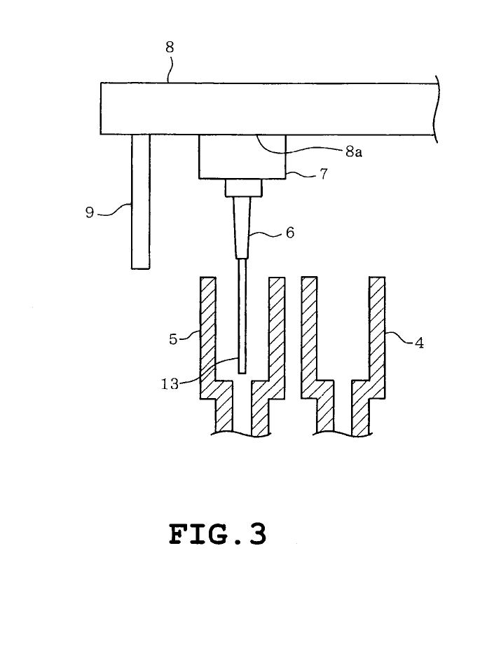

The operation of the above described coater apparatus 1 will be described with further reference to FIG. 3 through an example in which coater apparatus 1 is used to coat resist on wafer W. When in standby, resist nozzle 6 and chemical liquid nozzles 10 are stored inside solvent bath 4, whereas prewet nozzle 9 is stored inside dummy dispense port 5 as shown in FIG. 1. In this example, resist nozzle 6 is mounted on nozzle mount 8a provided on the underside of hand 8 of the robotic arm.

Resist nozzle 6 executes dummy dispensing on a regular basis or prior to resist coating. The following is one example of how dummy dispensing is executed. Hand 8 is raised from the standby position shown in FIG. 1 and further moved sideways to relocate resist nozzle 6 above dummy dispense port 5 as shown in FIG. 3. Prior to the execution of dummy dispensing, the air around dummy dispense port 5 is ionized. This is illustrated in FIG. 1 which shows soft X-ray radiation ionizer 11 being driven or activated to radiate soft X-ray indicated by broken lines to ionize the air around dummy dispense port 5, resist nozzle 6, and hand 8. Thus, if dummy dispense port 5 and its nearby components or air carry static electricity, the static electricity can be neutralized by the above described air ionization.

After ionizing the air around dummy dispense port 5, resist 13 is dispensed from the tip of resist nozzle 6 as shown in FIG. 3 and dummy dispensed or disposed as waste into dummy dispense port 5. In case resist 13 being dispensed from resist nozzle 6 carries positive or negative static electricity, electric charge residing on the surface of resist 13 attracts and is neutralized by the nearby floating negative or positive ions of opposite polarity. This means that, the static electricity carried by resist 13 dispensed from resist nozzle 6 is removed by the ions.

As a result, resist 13 dispensed from resist nozzle 6 drops vertically downward as shown in FIG. 3, thereby reliably preventing the inner peripheral wall of dummy dispense port 5 from being contaminated by attachment of resist 13 which is one example of contaminants. Because the inner peripheral wall of dummy dispense port 5 can be kept free of contaminants, the tip of prewet nozzle 9 can be prevented from picking up contaminants when stored inside dummy dispense port 5 during standby.

In the absence of soft X-ray radiation ionizer 11, static electricity, if any, will remain unremoved from resist 13 being dispensed from resist nozzle 6. Thus, resist 13 carrying the static electricity will be dispensed or will drop toward the inner peripheral wall of dummy dispense port 5 leaving a curved trajectory. As a result, the inner peripheral wall of dispense port 5 is contaminated by resist 13 and/or other contaminants. When prewet nozzle 9 is stored in the contaminated dummy dispense nozzle 5, contaminants residing on the inner peripheral wall of dummy dispense port 5 may attach on the tip of prewet nozzle 9. Wafer W, being prewet with such contaminated prewet nozzle 9, may in turn be contaminated by the contaminants falling from prewet nozzle 9. The first embodiment however, reliably resolves such contamination problems by utilizing soft X-ray radiation ionizer 11 as described above. The static electricity carried by components such as dummy dispense port 5, resist nozzle 6, and hand 8 can also be removed by the ions produced by soft X-ray radiation ionizer 11.

In the first embodiment, soft X-ray radiation ionizer 11 is configured to radiate soft X-ray during a time period spanning between a first timing or point in time prior to the dummy dispensing of resist 13 from resist nozzle 6 and a second timing after completion of the dummy dispensing. Alternatively, soft X-ray radiation ionizer 11 may be configured to start the radiation of soft X-ray well before the dummy dispensing and consequently, the first timing.

For example, the radiation of soft X-ray may begin at a third timing when hand 8 and consequently resist nozzle 6 initiates the relocation to the position above dummy dispense port 5 for the execution dummy dispensing.

In another example, the radiation of the soft X-ray may begin at a fourth timing after the third timing and before hand 8/resist nozzle 6 reach the position above dummy dispense port 5, in other words, before the relocation of hand 8/resist nozzle 6 is terminated.

In still another example, the radiation of the soft X-ray may end at a fifth timing after the second timing in which the dummy dispensing has been completed.

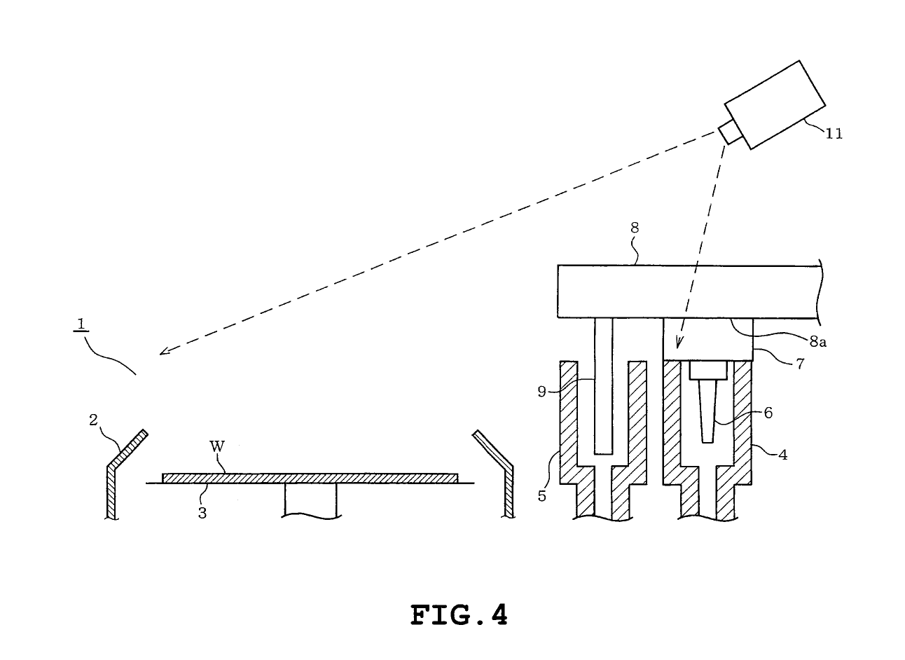

FIG. 4 illustrates a second embodiment and the elements substantially identical to those of the first embodiment are identified with identical reference symbols. In the second embodiment, soft X-ray radiation ionizer 11 is configured to radiate soft X-ray so as to cover a wider range compared to the first embodiment. FIG. 4 exemplifies the range of radiation of the soft X-ray being extended to components such as coater cup 2, wafer W, and spin chuck 3 and their periphery in addition to the dummy dispense port 5 and its periphery covered in the first embodiment. Apart from the above, the second embodiment remains the same in configuration from the first embodiment and thus, provides the operation and effect similar to those of the first embodiment. Because the radiation of soft X-ray is extended to cover a relatively wider range including coater cup 2, wafer W, and spin chuck 3 in addition to dummy dispense port 5, the second embodiment is capable of ionizing the air or the atmosphere around the foregoing components, thereby removing or neutralizing the static electricity carried by the foregoing components.

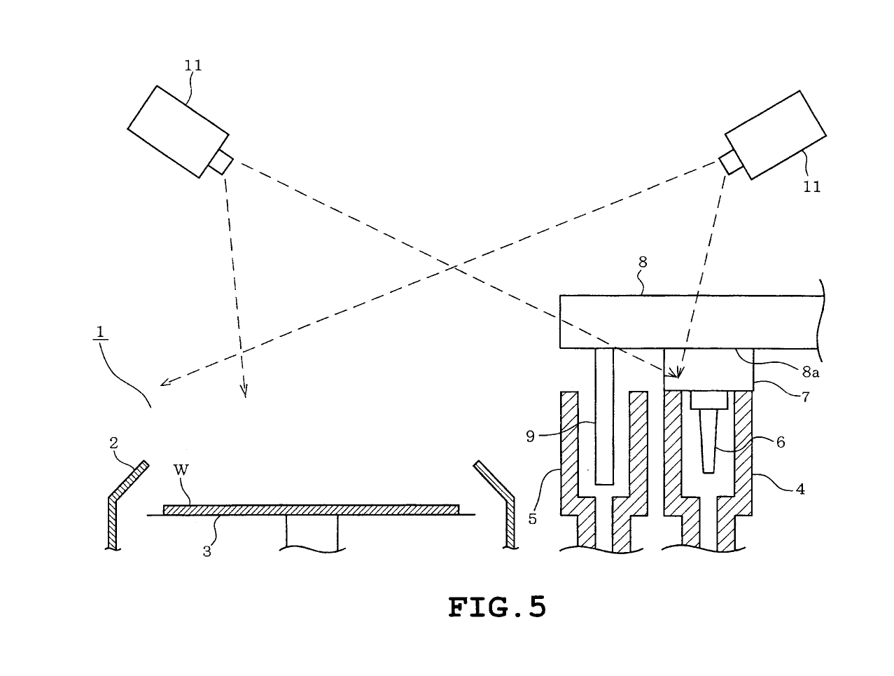

FIG. 5 illustrates a third embodiment and the elements substantially identical to those the second embodiment are identified with identical reference symbols. In the third embodiment, more than one soft X-ray radiation ionizer 11 is provided as shown in FIG. 5. The multiple soft X-ray radiation ionizers 11 are configured to radiate soft X-ray around components such as dummy dispense port 5, coater cup 2, wafer W, and spacer chuck 3. Apart from the above, the third embodiment remains the same in configuration from the second embodiment and thus, provides the operation and effect similar to those of the second embodiment. Because the soft X-ray radiation produced by multiple soft X-ray radiation ionizers 11 effectively reaches dummy dispense port 5, coater cup 2, wafer W, spin chuck 3 and their periphery, the third embodiment is capable of more reliably ionizing the air or the atmosphere around the foregoing components and thereby more reliably removing or neutralizing the static electricity carried by the foregoing components.

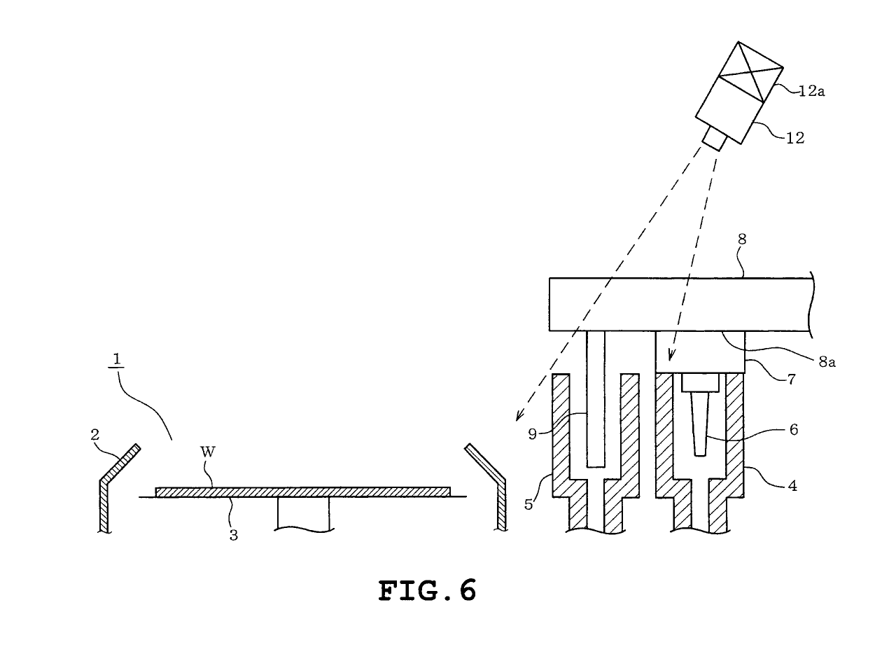

FIG. 6 illustrates a fourth embodiment and the elements substantially identical to those of the first embodiment are identified with identical reference symbols. In the fourth embodiment, soft X-ray radiation ionizer 11 employed in the foregoing embodiments is replaced by corona discharge ionizer 12. As shown in FIG. 6, corona discharge ionizer 12 contains blower 12a and a discharge electrode not shown. The discharge electrode produces corona discharge to ionize the air around the discharge electrode. Then, the ionized air is blown to dummy dispense port 5 and its periphery by blower 12a. Apart from the above, the fourth embodiment remains the same in configuration from the first embodiment and thus, provides the operation and effect similar to those of the first embodiment.

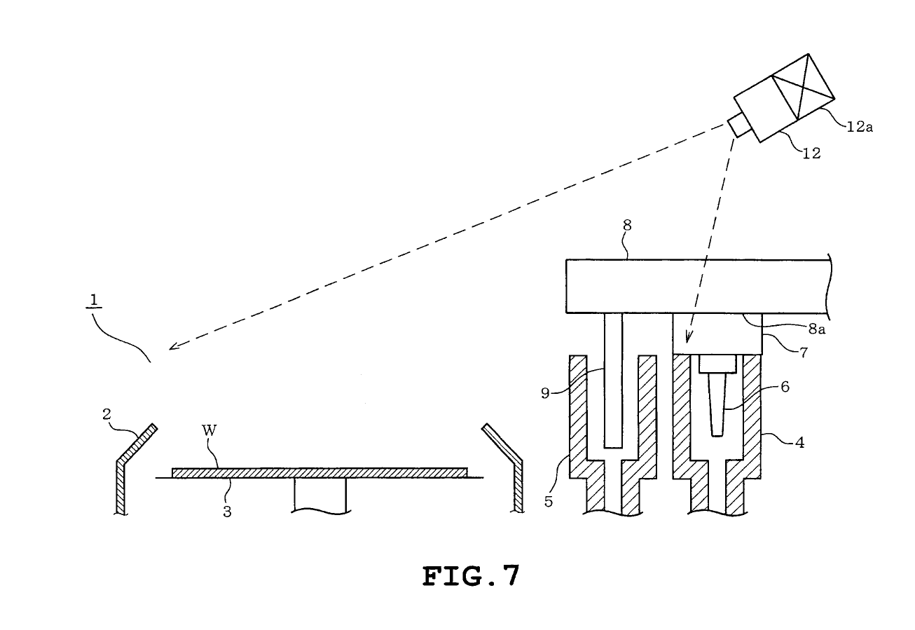

FIG. 7 illustrates a fifth embodiment and the elements substantially identical to those of the fourth embodiment are identified with identical reference symbols. In the fifth embodiment, corona discharge ionizer 12 is configured to blow ionized air onto components such as coater cup 2, wafer W, and spin chuck 3 and their periphery in addition to the dummy dispense port 5 and its periphery. Apart from the above, the fifth embodiment remains the same in configuration from the fourth embodiment and thus, provides the operation and effect similar to those of the fourth embodiment. Because the ionized air is blown to the periphery of coater cup 2, wafer W, and spin chuck 3 in addition to the periphery of dummy dispense port 5, the fifth embodiment is capable of removing or neutralizing the static electricity carried by the foregoing components.

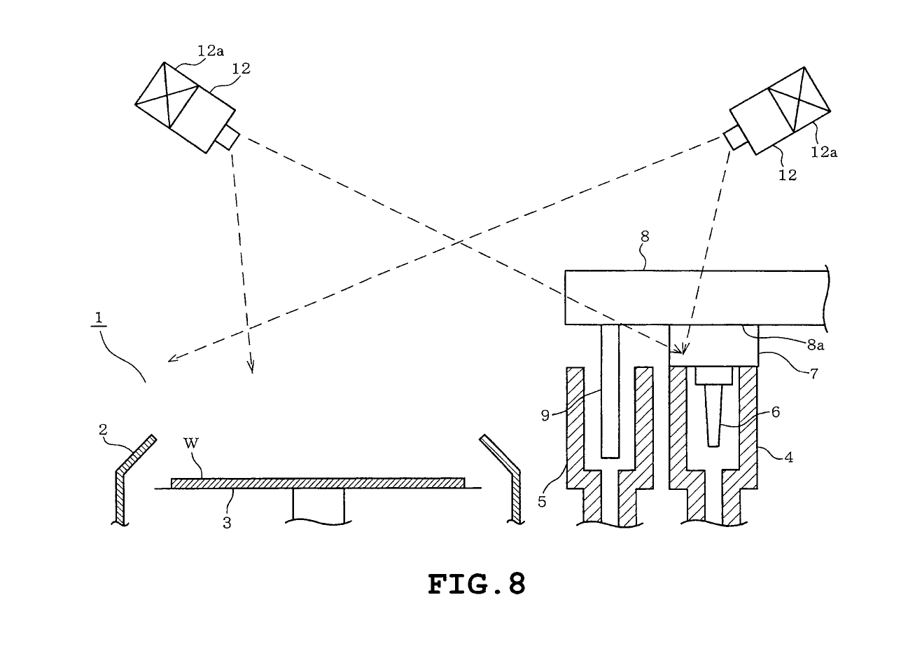

FIG. 8 illustrates a sixth embodiment and the elements substantially identical to those of the fifth embodiment are identified with identical reference symbols. In the sixth embodiment, more than one corona discharge ionizers 12 are provided as shown in FIG. 8. The multiple corona discharge ionizers 12 are configured to blow the ionized air to the components such as dummy dispense port 5, coater cup 2, wafer W, and spacer chuck 3 and their periphery. Apart from the above, the sixth embodiment remains the same in configuration from the fifth embodiment and thus, provides the operation and effect similar to those of the fifth embodiment. Because the ionized air is blown to the periphery of dummy dispense port 5, coater cup 2, wafer W, and spin chuck 3 by multiple corona discharge ionizers 12, the sixth embodiment is capable of more reliably removing or neutralizing the static electricity carried by the foregoing components.

The foregoing embodiments may be modified or expanded as follows.

In the foregoing embodiments, soft X-ray radiation ionizer 11 or corona discharge ionizer 12 was activated during the dummy dispensing of resist 13 from resist nozzle 6 to remove the static electricity carried by resist 13.

Alternatively, soft X-ray radiation ionizer 11 or corona discharge ionizer 12 may be activated during the dummy dispensing of other types of chemical liquids dispensed from other chemical liquid nozzles 10 as well to remove the static electricity carried by such chemical liquids. Examples of such chemical liquids include liquid silica based compounds and polysilazane solution used in forming an SOG (Spin On Glass) film.

Further in the foregoing embodiments, soft X-ray radiation ionizer 11 or corona discharge ionizer 12 was activated to ionize the air around dummy dispense port 5 or the air around dummy dispense port 5, coater cup 2, wafer W, and spin chuck 3.

Alternatively, the air around dummy dispense port 5, coater cup 2, wafer W, spin chuck 3, and also solvent bath 4 may be ionized.

Still further, soft X-ray radiation ionizer 11 or corona discharge ionizer 12 used in the foregoing embodiments may be replaced by other types of ionizers.

In the foregoing embodiments, one or more ionizers are provided that ionizes the air or atmosphere around at least the dummy dispense port. Thus, chemical liquid(s) dispensed from the chemical liquid nozzle(s) is prevented from attaching to the inner peripheral wall of the dummy dispense port during dummy dispensing. As a result, the tip of the prewet nozzle stored in the dummy dispense port will not pick up any contaminants, which in turn prevents wafer contamination during wafer prewetting.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A coater apparatus that coats a substrate with a chemical liquid comprising:
a chemical liquid nozzle that dispenses the chemical liquid onto the substrate;
a solvent nozzle that dispenses a solvent onto the substrate;
a solvent bath that contains a solvent and that stores a tip of the chemical liquid nozzle when the chemical liquid nozzle is in standby such that the tip is exposed to a solvent vapor;
a dummy dispense port that exhausts the chemical liquid being dummy dispensed from the chemical liquid nozzle and that stores the solvent nozzle when the solvent nozzle is in standby; and
an ionizer that ionizes an atmosphere around the dummy dispense port.

2. The coater apparatus according to claim 1, wherein the ionizer further ionizes an atmosphere around the substrate.

3. The coater apparatus according to claim 2, wherein more than one ionizer is provided.

4. The coater apparatus according to claim 1, further comprising a coater cup and a spin chuck that is provided rotatably inside the coater cup and that allows secure placement of the substrate, wherein the ionizer further ionizes an atmosphere around the substrate, the spin chuck, and the coater cup.

5. The coater apparatus according to claim 4, wherein the ionizer further ionizes an atmosphere around the solvent bath.

6. The coater apparatus according to claim 1, further comprising a movable robotic arm terminating in a hand, wherein the chemical liquid nozzle and the solvent nozzle are mounted on the hand and are moved together by the movement of the hand.

7. The coater apparatus according to claim 6, wherein more than one chemical liquid nozzle is provided and the hand allows detachable attachment of any one of the chemical liquid nozzles.

8. The coater apparatus according to claim 7, wherein a tip of each chemical liquid nozzle which is not attached to the hand is exposed to the solvent vapor within the solvent bath.

9. The coater apparatus according to claim 1, wherein the ionizer comprises a soft X-ray radiation ionizer.

10. The coater apparatus according to claim 1, wherein the ionizer comprises a corona discharge ionizer.

11. The coater apparatus according to claim 1, further comprising a controller, wherein the controller relocates the chemical liquid nozzle to a position above the dummy dispense port to dummy dispense the chemical liquid and activates the ionizer to ionize the atmosphere around the dummy dispense port prior to the dummy dispensing.

12. The coater apparatus according to claim 11, wherein the controller activates the ionizer when the chemical liquid nozzle is located at the position above the dummy dispense port and inactivates the ionizer after completing the dummy dispensing.

13. The coater apparatus according to claim 11, wherein the controller activates the ionizer when the relocation of the chemical liquid nozzle to the position above the dummy dispense port is initiated and inactivates the ionizer after completing the dummy dispensing.

14. The coater apparatus according to claim 11, wherein the controller activates the ionizer during a period of the relocation of the chemical liquid nozzle to the position above the dummy dispense port falling after the chemical liquid nozzle initiates the relocation and before the chemical liquid nozzle completes the relocation and inactivates the ionizer after completing the dummy dispensing.

15. A method of coating a substrate with a chemical liquid using a coater apparatus including a chemical liquid nozzle that dispenses the chemical liquid onto the substrate, a solvent nozzle that dispenses a solvent onto the substrate, a solvent bath that contains a solvent and that stores a tip of the chemical liquid nozzle when the chemical liquid nozzle is in standby such that the tip is exposed to a solvent vapor, and a dummy dispense port that stores the solvent nozzle when the solvent nozzle is in standby, the method, comprising:
relocating the chemical liquid nozzle to a position above the dummy dispense port;
ionizing an atmosphere around the dummy dispense port; and
dummy dispensing, after ionizing, to exhaust the chemical liquid into the dummy dispense port.

16. The method according to claim 15, wherein ionizing further ionizes an atmosphere around the substrate.

17. The method according to claim 15, further comprising prewetting the substrate with the solvent dispensed onto the substrate from the solvent nozzle and coating the substrate with the chemical liquid dispensed from the chemical liquid nozzle, wherein the chemical liquid comprises a resist.

18. The method according to claim 15, wherein ionizing employs an ionizer, activates the inonizer when the chemical liquid nozzle is located above the dummy dispense port for dummy dispensing, and inactivates the ionizer after completing the dummy dispensing.

19. The method according to claim 15, wherein ionizing employs an ionizer, activates the ionizer when the relocation of the chemical liquid nozzle to the position above the dummy dispense port for dummy dispensing is initiated, and inactivates the ionizer after completing the dummy dispensing.

20. The method according to claim 15, wherein ionizing employs an ionizer, activates the ionizer during a period of the relocation of the chemical liquid nozzle to the position above the dummy dispense port for dummy dispensing falling after the chemical liquid nozzle initiates the relocation and before the chemical liquid nozzle completes the relocation, and inactivates the ionizer after completing the dummy dispensing.
